(19) United States
(12) Patent Application Publication
(10) Pub. No.: US 2026/0221922 A1
(43) Pub. Date: Jul. 30, 2026

(54) ENERGY SUPPLY FOR A MULTIPHASE DRIVE

(71) Applicant: Innomotics GmbH, 90441 Nürnberg (DE)

(72) Inventors: KONRAD BRANDL, Thalmassing (DE); JONATHAN ROBINSON, Eindhoven (NL)

(73) Assignee: Innomotics GmbH, 90441 Nürnberg (DE)

(21) Appl. No.: 19/150,666

(22) PCT Filed: Dec. 27, 2023
(86) PCT No.: PCT/EP2023/087823

§ 371 Date: Jul. 24, 2025

(30) Foreign Application Priority Data
Jan. 25, 2023 (EP) 23153206.0

(51) Int. Cl. H02P 27/06; B60L 15/06; H02K 7/00; H02K 7/14; H02K 7/18; H02K 11/33; H05K 7/20

(52) U.S. Cl. CPC H02P 27/06; B60L 15/06; H02K 7/003; H02K 7/14; H02K 7/183; H02K 11/33; H05K 7/2089; B60L 2200/32; B60L 2210/10; B60L 2210/40; H02P 2201/03

(57) ABSTRACT

A multiphase drive system comprises a multiphase drive including a stator and converter modules and having an input DC voltage of less than 100 V and a rated power of more than 300 kW. Each converter module supplies power to stator bars such that voltage or current of each bar is controlled separately by one converter module. An energy supply device is electrically connected to connections of the multiphase drive and generates a DC voltage for supply to the multiphase drive from an AC voltage. The energy supply device includes a voltage converter, a line section between voltage converter and the connections of the multiphase drive for transmitting electrical energy to the multiphase drive, and a rectifier. The voltage converter steps down voltage generated by the rectifier to a voltage of less than 100 V. The rectifier and parts of the multiphase drive are cooled using a same cooling principle.

The invention relates to an energy supply device for a multiphase drive, wherein the multiphase drive has an input voltage of less than 100 V and a rated power of more than 300 kW, in particular of more than 1 MW. The invention furthermore relates to a multiphase drive system comprising such an energy supply device and a multiphase drive. The invention also relates to a ship, a wind power installation, a compressor system or a pump system comprising such a multiphase drive system.

At present, a wide range of electrical machines designed with three-phase connections are available on the market. In these, the stator bars are Interconnected such that they form windings and are connected to the phase connections. Instead of bars, the stator may also be formed by conductors, in particular copper conductors, aligned in parallel in a slot. Hereinafter, the designation “bars” also encompasses the design consisting of multiple or a plurality of conductors in a respective slot.

An alternative design of an electrical machine is to supply power to each bar separately with a converter module. The number of phases of such an electrical machine thus corresponds to the number of slots in the stator. The converter modules provided for supplying power to the individual slots form a converter that is connected directly to the electrical machine and forms a functional unit therewith.

Such an electrical machine having a converter formed of converter modules is also referred to as a multiphase drive. Its input voltage often forms a DC voltage.

The magnetic field required for the operation of the electrical machine is generated by high currents in the stator bars, with at the same time comparatively low voltages. Known applications of the order of about 50 KW draw the power required for operation directly from a battery.

The invention is based on the object of improving the energy supply of a powerful multiphase drive.

This object is achieved by an energy supply device for a multiphase drive, wherein the energy supply device is configured to generate a DC voltage to be supplied to the multiphase drive from an input voltage present at a grid connection point, in particular an AC voltage of an energy supply grid, wherein the multiphase drive has an input DC voltage of less than 100 V and a rated power of more than 300 KW, in particular of more than 1 MW, wherein the energy supply device has a voltage converter, wherein the energy supply device has a line section for transmitting electrical energy, by way of DC voltage, to the multiphase drive with a rated voltage of less than 100 V. This object is furthermore achieved by a multiphase drive system comprising such an energy supply device and a multiphase drive having an input DC voltage of less than 100 V and a rated power of more than 300 KW, in particular of more than 1 MW, wherein the energy supply device is electrically connected to the multiphase drive, in particular to connections of the multiphase drive. This object is also achieved by a ship as claimed in claim 11, a wind power installation as claimed in claim 12, a compressor system as claimed in claim 13 and a pump system as claimed in claim 14 having such a multiphase drive system.

Further advantageous embodiments of the invention are specified in the dependent claims.

The invention is based, inter alia, on the finding that a multiphase drive is also able to be supplied with power from an energy supply grid by way of the proposed energy supply device, rather than from a battery, with low losses. The low voltage at the bars of the multiphase drive results in correspondingly high currents for the required power range. In one typical application, this bar AC voltage is approximately 22 V with a bar AC current of approximately 600 A. The supply voltage of the converter integrated in the multiphase drive on the DC side, that is to say on the DC voltage side, is then approximately V_{DC}=62 V. The AC voltage level at a grid connection point of an AC voltage grid for supplying power to electric drives is 690 V for low voltages and typically 6 and 10 kV for high voltages. The voltage value may however also assume any value between, below or above this. When power is supplied from a DC voltage grid, the connection to the grid connection point is made at a voltage of preferably 690 V or 5 kV. Any value between or above this is also possible. This means that the voltage of the energy supply grid at the grid connection point is considerably higher than the voltage level supplied to the multiphase drive.

The low voltages of the multiphase drive result in principle from the fact that the electrical machine of the multiphase drive is designed with a half-winding by virtue of power being supplied to the individual bars in the stator. A whole winding corresponds here to an arrangement of two bars in the form of outgoing and returning conductors.

Starting from the grid connection point of the energy supply grid, the voltage at the grid connection point is converted, by way of the voltage converter, to a lower voltage that is able to be supplied to the multiphase drive. Depending on how the energy supply grid is embodied, a transformer, a DC-DC converter or a converter may be used as voltage converter, for example. The converter may in this case convert an AC voltage of the energy supply grid into a DC voltage to be supplied directly to the multiphase drive. The converter may then also be referred to as a rectifier.

A DC-DC converter is also referred to as a DC voltage controller or DC chopper.

The on-board network of a ship is often designed as a medium-voltage DC voltage system. The multiphase drive system is therefore particularly suitable for a ship, since conversion into a different on-board voltage may in some cases be dispensed with. If for example, on the other hand, the ship's on-board network is designed for a voltage of 690 V or 5 kV, then it is particularly simple to adapt the voltage using a DC chopper.

The advantages that the proposed solution entails in the multiphase drive system not only concern the energy supply device, but also in particular relate to the operation of the multiphase drive. A solution accepted by the market and attractive to customers is a positive effect on the success of the multiphase drive.

The energy supply device may be arranged outside the multiphase drive. In this case, the line section extends to the connections of the multiphase drive. As an alternative, it is possible to arrange the energy supply device at least partially within the multiphase drive. In this case, at least one voltage converter is arranged in the housing of the multiphase drive. This voltage converter is located on the side of the electrical machine, viewed from the connections of the multiphase drive. The line section then extends to the converter modules of the multiphase drive. The line section begins at the point where the intended voltage for the line portion is less than 100 V.

The use of such a multiphase drive with the proposed energy supply device or of such a multiphase drive system, as already illustrated, is particularly advantageous for the driving of a ship. This use has proven to be favorable due to the high power and the requirements in terms of dynamic control over a wide range of torque and speed. In addition, the low-voltage line section may be selected to be short. This makes it possible to utilize the advantages of the high dynamic response and the large speed and torque range for the drive. The multiphase drive system likewise meets the high demands in terms of redundancy and fall-safety for watercraft. Use in a wind power installation is also advantageous, since in this case too the energy supply device is able to be arranged in spatial proximity to the multiphase drive, and therefore not only is a low-loss drive provided, but also the energy is able to be supplied redundantly to the energy supply grid. Use for compressor and pump systems is furthermore also advantageous. Not only does fail-safety represent a significant competitive advantage, but also it is possible to respond quickly to changes in operating parameters through the supply of power to the individual bars of the electrical machine.

In one advantageous embodiment of the invention, the line section has a length of less than 2 m. In order that the energy supply device exhibits low losses, it is proposed to limit the line section operated with a voltage of less than 100 V to a length of less than 2 m. The losses that the high currents entail may thus be reduced to a tolerable level. The two units, the multiphase drive and the voltage converter, are electrical components that, on the one hand, have to be protected by way of an appropriate housing due to the rotating parts and the high voltages. The line section constitutes the electrical connection, or at least part of the electrical connection, between these two units. Due to the low voltage of this connection, it is not necessary to take any measures with regard to contact protection. This affords a very high degree of flexibility in terms of how this connection is embodied. These connections may be designed as cable connections, or else as a busbar. The connection may in this case be adapted to the conditions resulting from the installation of the two units, the multiphase drive and the voltage converter. A special housing or cover is not required for the line section. Due to the short extent of the line section, the losses of the multiphase drive are able to be reduced significantly. In particular, if the energy supply device is arranged in the housing of the multiphase drive, this also achieves, in addition to low losses, only minor formation of interfering magnetic fields.

In a further advantageous embodiment of the invention, the voltage converter is designed as a transformer or as a DC-DC converter. The transformer constitutes a simple and reliable way of modifying or adapting an AC voltage when power is supplied from an AC voltage grid. The transformer has a high weight due to its iron core. This represents a special requirement in terms of the installation site, for example special requirements in terms of the foundations. These special requirements mean that the installation of the transformer is not particularly flexible. This drawback is able to be compensated for easily especially by the only low-voltage line section, which does not require any special contact protection precautions, since the transformer is able to be connected flexibly to the multiphase drive by way of the line section.

In the case of a DC voltage grid, the voltage converter may be designed as a DC-DC converter. The DC-DC converter in this case uses semiconductors to convert a first DC voltage into a second DC voltage, inexpensively and reliably. The DC-DC converter is in this case preferably arranged in a control cabinet, for contact protection reasons, inter alia. The DC-DC converter may in this case be arranged in spatial proximity to the grid connection point. However, if it is located at a greater distance from the multiphase drive, it may be advantageous to arrange the DC-DC converter in proximity to the multiphase drive in order to keep the line portion operated with low voltage as short as possible. The line section is used to transmit the energy from this control cabinet to the multiphase drive at low voltage and over a short distance.

In a further advantageous embodiment of the invention, the line section is designed at least partially as a busbar. Busbars have the advantage of also being able to provide large cross sections having a high current-carrying capacity with low electrical losses. They are therefore particularly suitable for embodying the line section. At the same time, it is possible to dispense with insulation in order to ensure contact protection, since the voltage that is used is sufficiently low, in particular with regard to contact protection. This is likewise advantageous for the use of the busbars, since these usually have no insulation on their surface. The absence of insulation also improves heat dissipation caused by electrical losses. The heat may be dissipated directly from the material of the busbar, preferably copper, to the surroundings without this being hindered by a layer of insulation. The busbar thus represents a particularly advantageous embodiment of the line section, especially for use in an energy supply device for the multiphase drive, due to the various advantages.

In a further advantageous embodiment of the invention, the energy supply device has a further voltage converter. If the distance to be bridged between the grid connection point and the multiphase drive is large, then a further voltage converter may be used to generate a further voltage level for the transmission of the electrical energy. In this case, the voltage converter may for example be designed as a further transformer, in the case of operation on an AC voltage grid, or as a further DC-DC converter, in the case of operation on a DC voltage grid. A voltage between 100 V and 1000 V may be provided here for a further line portion. This further line portion is particularly suitable for carrying out low-loss energy transmission over a distance of more than 2 m. In particular, the further line portion makes it possible to limit the length of the line section with a voltage of less than 100 V to an extent of less than 2 m. For this purpose, the two voltage converters are arranged at the two ends of the further line portion.

The division into a line section and a further line portion particularly advantageously makes it possible to adapt the energy supply device to the conditions at the installation site. The multiphase drive may in this case also be arranged away from the grid connection point. In the proposed arrangement, electrical losses occur to an acceptable degree. Moreover, the transmission paths also do not have any voltages above 1000 V, which would disproportionately increase the cost of insulation needed to comply with contact protection.

The further voltage converter means that the energy supply system is able to be adapted to the conditions at the installation site, in a particularly advantageous and flexible manner.

In a further advantageous embodiment of the invention, the energy supply device has a rectifier. In order to supply DC voltage to the multiphase drive, it is advantageous to arrange a rectifier in the energy supply device. This may be used to convert an AC voltage, which is present at the grid connection point and possibly converted via one or more voltage converters, into a DC voltage to be supplied to the multiphase drive. The multiphase drive is thus also able to be supplied with power with high efficiency from an AC voltage grid.

In a further advantageous embodiment of the invention, the multiphase drive has converter modules, wherein the converter modules are each designed to supply power to the bars of the stator of the multiphase drive. The current per bar is able to be set precisely by virtue of the bars being supplied with power by the corresponding converter modules. This makes it possible to define and optimize the number of pole pairs depending on the operating point of the multiphase drive. The multiphase drive is thereby able to be operated at a favorable operating point with low losses. At the same time, the characteristic curve of the motor is thus Increased, meaning that higher torques and higher speeds are able to be achieved.

In a further advantageous embodiment of the invention, the energy supply device has a rectifier, wherein the rectifier and at least parts of the multiphase drive are cooled using the same cooling principle. A rectifier arranged in the energy supply device may be dispensed with if the multiphase drive already comprises a rectifier in its functional unit. In this case, an AC voltage may then be supplied to the multiphase drive. Moreover, the rectifier, like the converter, may be integrated into the housing of the multiphase drive. The cooling system may in particular be designed as a common cooling system for the rectifier and the converter. It has also proved to be advantageous here for the rectifier and at least parts of the multiphase drive, such as for example the converter, to be cooled using the same type of cooling, for example the same air flow or the same fluid flow.

It is particularly advantageous for the rectifier and parts of the multiphase drive to be cooled using a common cooling circuit. This saves on the components needed to form two cooling circuits. In this case, the coolant may first cool the lower-temperature components and then be channeled in the cooling circuit to the higher-temperature components. The cooling circuit may thereby easily be used for different components.

In a further advantageous embodiment of the invention, the voltage converter and the line section are arranged inside a housing of the multiphase drive. In this case, the electrical machine behaves like a motor with a connection voltage significantly higher than 100 V, for example a DC voltage of 690 V or an AC voltage of more than 1000 V. The multiphase drive then forms a structural unit comprising the voltage converter and the line section with a voltage of less than 100 V. The voltage conversion, carried out for example by a DC-DC converter or a converter, then takes place directly in the housing of the multiphase drive. The voltage converter may thus also be connected to the cooling circuit of the multiphase drive. An existing motor with a conventional design may therefore be easily exchanged for and replaced by the multiphase drive system. In other words, the multiphase drive system is a connection-compatible replacement for existing motors.

The Invention is described and explained in more detail below with reference to the exemplary embodiments illustrated in the figures. It is shown in:

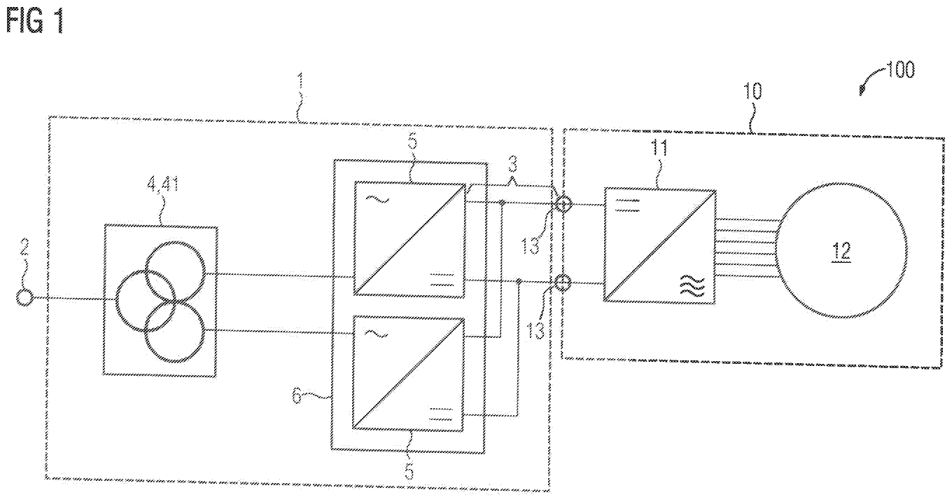

FIG. 1 to FIG. 4 exemplary embodiments of the energy supply device and of the multiphase drive system,

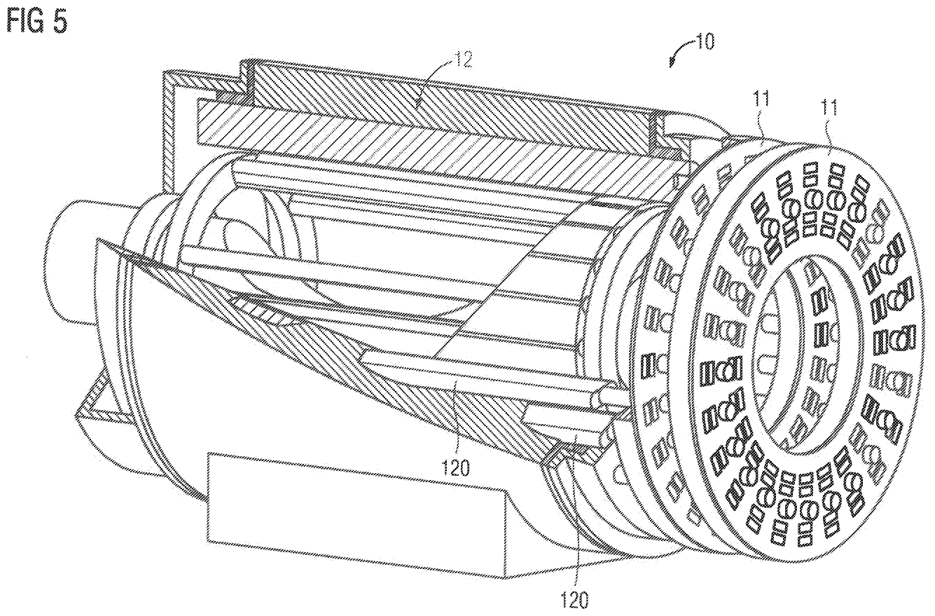

FIG. 5 to FIG. 7 exemplary embodiments of the multiphase drive,

FIG. 8 a ship,

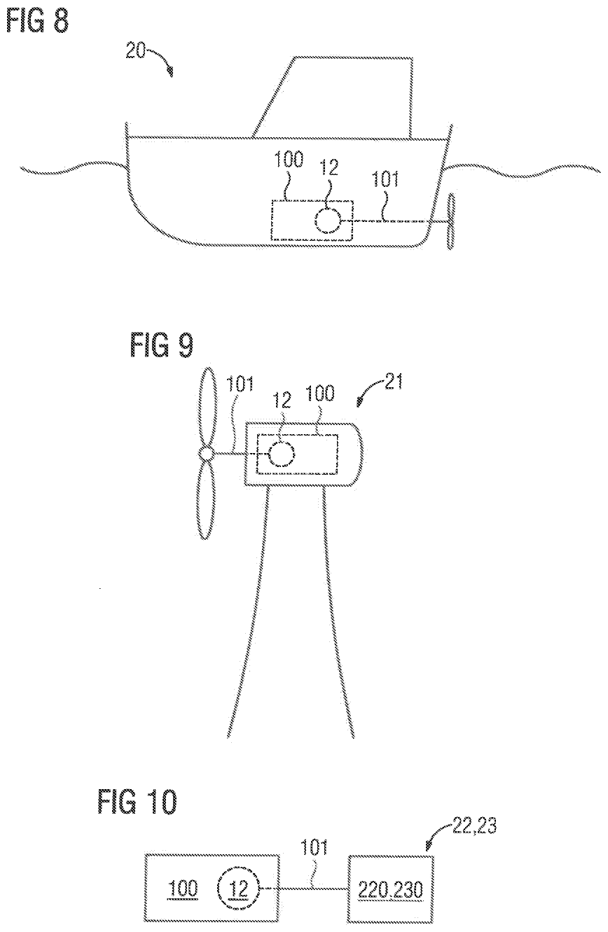

FIG. 9 a wind power installation, and

FIG. 10 a compressor system or pump system.

FIG. 1 shows a multiphase drive system 100 comprising an energy supply device 1 and a multiphase drive 10. The energy supply device 1 transmits electrical energy from a grid connection point 2 of an energy supply grid to connections 13 of the multiphase drive 10. In this exemplary embodiment, in a first step, a voltage converter 4, designed as a transformer 41, is used to modify the amplitude of an AC voltage at the grid connection point 2. A further voltage converter 6, formed in this example by two rectifiers 5 arranged in parallel, converts the AC voltage formed by the transformer 41 into a DC voltage that is supplied to the multiphase drive 10. In this case, a line section 3 between the voltage converter 6 and the connections 13 of the multiphase drive 10 is formed such that the DC voltage present there assumes a value of less than 100 V. In addition, the length of the line section 3 is less than 2 m in order to keep electrical losses low.

In addition to the electrical machine 12, the multiphase drive 10 has converter modules 11 that supply electrical energy to the individual bars of the stator. The electrical energy is supplied to the multiphase drive 10 via the connections 13 of the multiphase drive 10.

The section of the line portion between the connections 13 of the multiphase drive 10 and the converter modules 11 of the multiphase drive 10 has been ignored for the consideration of the losses caused by the low voltage and the high currents due to its short extent. This extent is significantly shorter than the length of the line section 3.

The advantages of this arrangement are now that it is possible to provide and implement a cost-effective, reliable energy supply device 1 using the illustrated components, such as the transformer 41 and the rectifier 5. On its primary side, the transformer 41 has to be adapted to the voltage level available to the customer at the grid connection point 2, that is to say the primary winding has to be designed for the respective supply voltage of for example 10 kV, 6 kV or 690 V. The output voltage of the secondary winding, on the other hand, has to be aligned with the DC voltage level of the multiphase drive 10. In this case, the rectifier 6 may be connected to or integrated into both the transformer 41 and the multiphase drive 10. The in principle high currents mean that it is necessary to provide a short line section from the transformer 41 to the rectifier 5 (rectifier 5 on/in the multiphase drive 10) and/or from the rectifier 5 to the multiphase drive 10 (rectifier 5 on/in the transformer 41) in both cases. It is important that the line section 3 with a voltage of less than 100 V is designed to be short, that is to say with a length of less than 2 m. Ideally, the components transformer 41, rectifier 5 and multiphase drive 10 may be arranged spatially such that the high DC currents are transmitted by way of short busbars. This component arrangement is preferable from a technical viewpoint, since there is no need to take any measures to reduce AC losses in the cables when transmitting the DC currents. The footprint of the rectifier 5 is comparable to the footprint of the converter modules 11 in the multiphase drive 10, for example due to the similar power. The same cooling principle may also be applied for the rectifier 5.

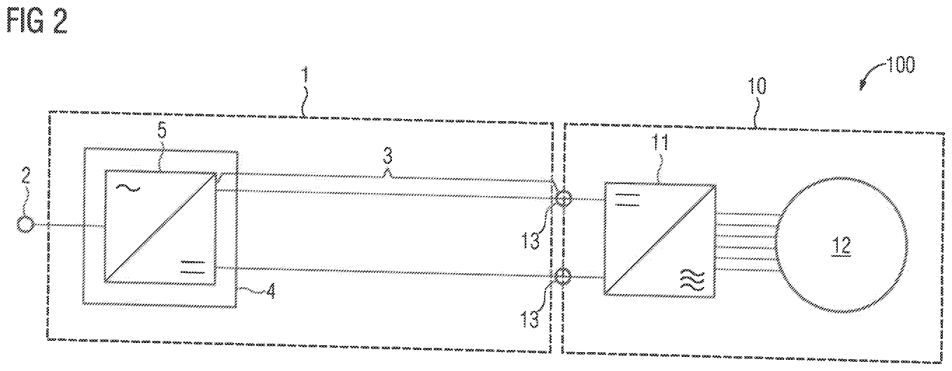

FIG. 2 shows a further exemplary embodiment of a multiphase drive system 100 having an alternatively embodied energy supply device 1. To avoid repetitions, reference is made to the description of FIG. 1 and to the reference signs introduced therein.

In this exemplary embodiment, the energy supply device 1 essentially has only the voltage converter 4, which is designed for example as a rectifier 5, if for example an AC voltage is present at the grid connection point 2. In this case, the voltage converter 4 may also comprise multiple rectifiers 5, which are for example arranged in a series circuit and/or parallel circuit. As an alternative, the voltage converter 4 may also be designed as a DC-DC converter 42, if for example a DC voltage is present at the grid connection point 2. From this rectifier 5, the electrical energy is transmitted to the connections 13 of the multiphase drive 10 by way of the line section 3 of less than 2 m at a DC voltage of less than 100 V, with low losses.

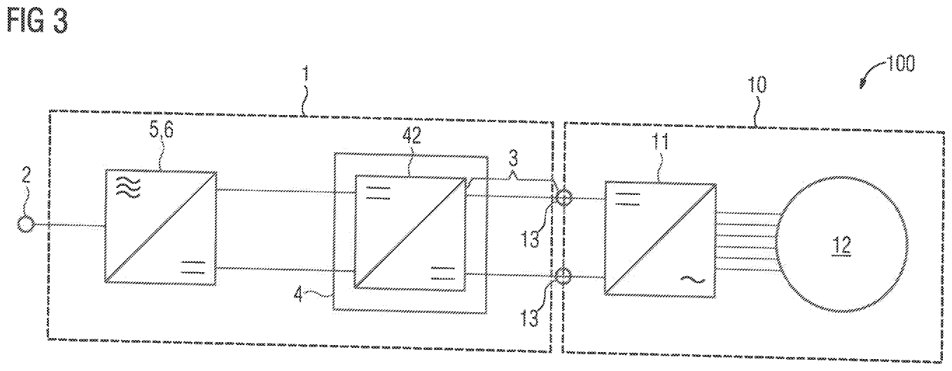

FIG. 3 shows a further exemplary embodiment of a multiphase drive system 100 having an alternatively embodied energy supply device 1. To avoid repetitions, reference is made to the description of FIGS. 1 and 2 and to the reference signs introduced therein.

In this exemplary embodiment, two voltage converters 4, 6 are present. A first of the voltage converters 4 is designed here as a DC-DC converter 42. As an alternative, the voltage converter 4 may also have multiple DC-DC converters 42. It converts a DC voltage generated by a further voltage converter 6 of the two voltage converters 4, 6 into a lower voltage with which the multiphase drive 10 is operated.

This arrangement is expedient if there is a relatively large distance, in particular a distance of more than 2 m, between the grid connection point 2 and the multiphase drive 10. Energy may then be transmitted with a higher voltage over a longer distance between the rectifier 5 and the DC-DC converter 42, before the DC voltage is stepped down by the DC-DC converter 42 to a DC voltage of less than 100 V with which the multiphase drive 10 is operated at its connections 13. In this case too, it is possible to ensure that the line section 3 between the DC-DC converter 42 and the connections 13 of the multiphase drive 10 is designed, with a maximum length of 2 m, to be appropriately short and low-loss. In addition, a transformer 41 may also additionally be arranged between the rectifier 5 and the grid connection point 2.

In this case, the transformer 41 may, but not necessarily, be adapted on its primary side to the voltage level available to the customer. In other words, the primary winding is designed for the respective supply voltage of for example 10 kV, 6 kV or 690 V. The rectifier 5, designed as a medium-voltage rectifier, is arranged on the secondary side of the transformer 41. In one advantageous embodiment, the transformer 41 and the rectifier 5 may in this case form a structural unit. The downstream DC-DC converter 4, 42, also referred to as DC transformer, takes over the voltage adaptation between the medium-voltage rectifier 5 and the multiphase drive 10. Ideally, the DC-DC converter 42 may be positioned directly on the multiphase drive 10. The electrical connection is thereby able to be designed for example as a cable connection from the rectifier 5 to the DC-DC converter 42, in conventional fashion and without any particular spatial proximity.

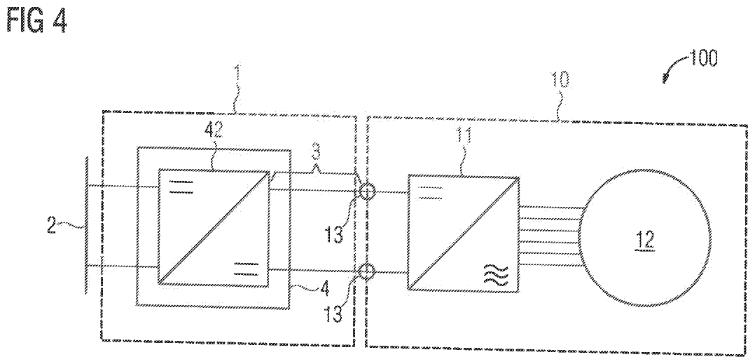

FIG. 4 shows a multiphase drive system 100 comprising an energy supply device 1 that is connected to a grid connection point 2 at which a DC voltage is present. In this exemplary embodiment, the voltage converter 4 is designed as a DC-DC converter 42. The energy supply device 1 in this case comprises, in addition to the DC-DC converter 42, the line section 3 that electrically connects the DC-DC converter 42 to the connections 13 of the multiphase drive 10. The line section 3 has a voltage of less than 100 V and exhibits low losses due to its length of less than 2 m.

FIG. 4 additionally shows how the multiphase drive 10 is able to be supplied with energy in a medium-voltage grid of a customer with a DC voltage at the grid connection point 2. Compared to the embodiment according to FIG. 3, the optional transformer 41 and the rectifier 5, designed as a medium-voltage rectifier, are dispensed with. The DC-DC converter 42 may be arranged directly between the grid connection point 2 and the multiphase drive 10. These medium-voltage grids, which are advantageous for the multiphase drive 10, may be found in particular in ship-related applications.

FIG. 5 shows a multiphase drive 10. In addition to the electrical machine 12, said multiphase drive has converter modules 11. The converter modules 11 and the electrical machine 12 are arranged in this case in the structural unit of the multiphase drive 10. Converter modules 11 are used to supply electrical energy to each bar of the stator of the electrical machine 12. In this case, the multiphase drive 10 is designed such that voltage and/or current of each bar of the stator is able to be controlled or regulated separately by one of the converter modules 11.

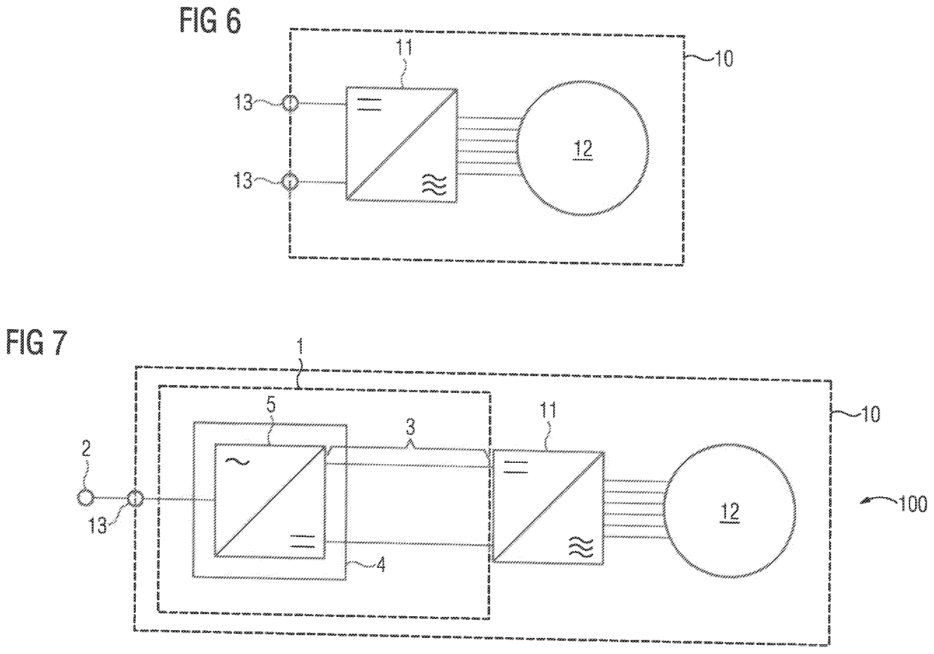

FIG. 6 shows the schematic design of such a multiphase drive 10. Electrical energy is supplied to the converter modules 11 at the connections 13, which are preferably arranged on the housing. The converter modules generate the voltages and/or currents required for the regulation or control for each bar of the electrical machine 12.

The voltage required to operate the multiphase drive 10 is a DC voltage, and the DC voltage value is less than 100 V.

FIG. 7 shows a further exemplary embodiment of the design of a multiphase drive 10. To avoid repetitions, reference is made to the description of FIG. 6 and to the reference signs introduced therein. In this exemplary embodiment, the multiphase drive 10 comprises the energy supply device 1 in full. In other words, the energy supply device 1 is part of the multiphase drive 10. The grid connection point 2 is connected directly to the connections 13 of the multiphase drive 10. As an alternative, it is also possible for a further voltage converter, not illustrated here, to be arranged between the grid connection point 2 and the connections 13 of the multiphase drive 10. In this case, the multiphase drive 10 comprises the energy supply device 1 only in part.

In this exemplary embodiment, the line section 3 extends from the voltage converter 4, which is designed as a rectifier 5, to the converter modules 11 of the multiphase drive 10.

FIG. 8 shows a ship 20, wherein the ship 20 is driven by the multiphase drive system 100. For this purpose, the ship's propeller is connected to the drive shaft 101 of the electrical machine 12 of the multiphase drive 10. To avoid repetitions, reference is made to the description of FIGS. 1 to 7 and to the reference signs Introduced therein.

FIG. 9 shows a wind power installation 21, wherein the wind power installation is able to feed the power drawn from the wind into an energy supply grid by way of the multiphase drive system. For this purpose, the rotor blades are mechanically connected to the drive shaft 101 of the electrical machine 12 of the multiphase drive 10. To avoid repetitions, reference is made to the description of FIGS. 1 to 7 and to the reference signs introduced therein.

FIG. 10 shows a compressor system 22 or a pump system. In order to drive the compressor 220 or the pump 230, these are mechanically connected to a drive shaft 101 of the electrical machine 12 of the multiphase drive 10. To avoid repetitions, reference is made to the description of FIGS. 1 to 7 and to the reference signs introduced therein.

1.-14. (canceled)

15. A multiphase drive system, comprising:
a multiphase drive having an input DC voltage of less than 100 V and a rated power of more than 300 KW, said multiphase drive including converter modules, each of the converter modules designed to supply power to bars of a stator of the multiphase drive such that voltage and/or current of each of the bars of the stator are controlled or regulated separately by one of the converter modules;
an energy supply device electrically connected to connections of the multiphase drive and designed to generate a DC voltage to be supplied to the multiphase drive from an AC voltage, present at a grid connection point, of an energy supply grid, said energy supply device including a voltage converter designed as a DC-DC converter, a line section between the voltage converter and the connections of the multiphase drive for transmitting electrical energy, by way of DC voltage, to the multiphase drive with a rated voltage of less than 100 V, and a rectifier, said voltage converter designed to step down a voltage generated by the rectifier to a voltage of less than 100 V with which the multiphase drive is operated at the connections thereof; and
a common cooling system designed for the rectifier and a converter formed by the converter modules so that the rectifier and parts of the multiphase drive are configured to be cooled using a same cooling principle.

16. The multiphase drive system of claim 15, wherein the rated power of the input DC voltage is more than 1 MW.

17. The multiphase drive system of claim 15, wherein the rectifier and the parts of the multiphase drive are cooled by a same cooling circuit.

18. The multiphase drive system of claim 15, wherein the line section has a length of less than 2 m.

19. The multiphase drive system of claim 15, wherein the line section is designed at least partially as a busbar.

20. The multiphase drive system of claim 15, wherein the multiphase drive includes a housing having an interior designed to accommodate the voltage converter, the converter modules and/or the line section.

21. A ship, comprising the multiphase drive system of claim 15.

22. A wind power installation, comprising the multiphase drive system of claim 15.

23. A compressor system, comprising:
the multiphase drive system of claim 15; and
a compressor mechanically coupled to a drive shaft of the multiphase drive of the multiphase drive system.

24. A pump system, comprising:
the multiphase drive system of claim 15; and
a pump mechanically coupled to a drive shaft of the multiphase drive of the multiphase drive system.

25. A method for operating the multiphase drive system of claim 15, a ship, a wind power installation, a compressor system or a pump system, the method comprising:
transmitting energy between the rectifier or a further voltage converter and the DC-DC converter with a voltage that is higher compared to a voltage of the line section; and
cooling with a common cooling system the rectifier and a converter formed by the converter modules so that the rectifier and parts of the multiphase drive are configured to be cooled using a same cooling principle.

26. The method of claim 25, wherein the rectifier and the parts of the multiphase drive are cooled by a same cooling circuit.

27. The method of claim 25, further comprising designing the line section at least partially as a busbar.

28. The method of claim 25, further comprising accommodating the voltage converter, the converter modules and/or the line section inside an interior of a housing of the multiphase drive.
